(19) United States
(12) Patent Application Publication
(10) Pub. No.: US 2007/0096198 A1
(43) Pub. Date: May 3, 2007

(54) Non-volatile memory cells and method for fabricating non-volatile memory cells

(76) Inventors: Franz Hofmann, Muenchen (DE); Johannes Luyken, Muenchen (DE); Michael Specht, Muenchen (DE); Wolfgang Rosner, Ottobrunn (DE)

Correspondence Address: SLATER & MATSIL LLP, 17950 PRESTON ROAD, SUITE 1000, DALLAS, TX, 75252, US

(21) Appl. No.: 11/262,309

(22) Filed: Oct. 28, 2005

(51) Int. Cl. H01L 29/788

(52) U.S. Cl. 257/316

(57) ABSTRACT

The invention relates to non-volatile memory cells. Further, the invention relates to a method for fabricating non-volatile memory cells. Memory cells are formed on a semiconductor wafer having a protruding element with a top surface. A transistor is formed having a first part, a second part, and a third part. The first part includes a first junction region and a first charge trapping layer on the top surface. The second part includes a second junction region and charge trapping layer on the top surface. The third part has a gate electrode and a gate dielectric layer at least partially on sidewalls of the protruding element. The gate electrode contacts the first and second charge trapping layers.

### TECHNICAL FIELD

The invention relates to non-volatile memory cells. Furthermore, the invention relates to a method for fabricating non-volatile memory cells. The invention particularly relates to the field of non-volatile memories having non-volatile memory cells. Such memory cells can advantageously be used e.g. in a virtual-ground-NOR architecture.

### BACKGROUND

The manufacturing of integrated circuits aims for continuously decreasing feature sizes of the fabricated components. Decreasing of feature sizes of the fabricated components can be achieved by printing elements using a lithographic patterning process with higher resolution capabilities. These concepts increase the resolution capabilities in semiconductor manufacturing. However, significant efforts and investments are needed to produce memories having the best possible resolution capabilities. On the other hand, however, significant efforts are needed to produce memory cells maintaining suitable electrical characteristics while scaling down the structural dimensions of memory cells.

In the past, efforts have been undertaken to increase the number of stored bits per memory cell. One example of known memory cells with buried bit lines and a virtual-ground-NOR architecture is described in the article: “NROM: A Novel Localized Trapping, 2-Bit Nonvolatile Memory Cell”, Boaz Eitan et al., IEEE Electron Device Letters, Vol. 21, No. 11, Nov. 2000, pp. 543-545, which is incorporated herein by reference.

In U.S. Pat. No. 5,768,192, which is incorporated herein by reference, a non-volatile memory is described in which electrons are trapped at a source region or a drain region respectively in a memory layer. The trapped electrons determine a threshold voltage of the transistor, which is configured as a semiconductor oxide nitride oxide semiconductor (SONOS) transistor. The presence of a charge at the source or drain respectively can be interpreted as a stored bit so that two bits can be stored in a cell of this kind. For programming, hot charge carriers are produced in the channel. The electrons are injected near to the drain region from the semiconductor material into the memory layer. In addition, a potential difference of typically 5 V is applied to a word line running via the gate in the direction from the source to the drain. The source region itself is connected to 0 V and the drain region, as a bit line, to 5 V. By reversing the applied voltage, charges can also be trapped in the source region.

In U.S. Pat. No. 6,673,677, which is incorporated herein by reference, a multi-bit memory cell is shown. The memory layer intended for trapping charge carriers at the source and the drain is limited to the edge region of the source region or drain region bordering the channel region. The memory layer is disposed between the boundary layers and embedded in a material with a higher energy band gap so that the charge carriers, which are trapped in the memory layer over the source region and over the drain region respectively, remain localized there. According to this disclosure, a larger number of charge and discharge cycles, even under unfavorable conditions, is possible even for a small distance from the source to the drain that is in a highly integrated memory, only 150 nm or less.

One of the most important development aims in the field of memory cells is the realization of increasingly smaller memory cells, i.e. the use of increasingly smaller chip areas per bit stored. Up to now, it has been considered advantageous to realize compact cells by means of buried, i.e. diffused bit lines that form the planar selection transistor for each memory cell as well. However, as their structural size decreases there is an increase of risk of a punch through between neighboring diffusion areas.

The problem arising in this connection is that further measures need to be implemented and, as a consequence, the utilization degree decreases. Accordingly, the advantage of the smaller memory cells, for which a higher process expenditure must be tolerated, diminishes.

### SUMMARY OF THE INVENTION

Embodiments of the invention provide non-volatile memory cells and a method for fabricating non-volatile memory cells scalable to smaller structural dimensions. Other embodiments of the invention provide non-volatile memory cells less sensitive to punch-through. Still other embodiments of the invention achieve non-volatile memory cells that are less sensitive to punch-through while occupying only a small area.

These and other technical advantages are generally achieved by embodiments of the invention that provide for nonvolatile memory cells. In a first embodiment, the nonvolatile memory cells include a semiconductor wafer that has a semi-conductive substrate structured to form at least one protruding element having a top surface. The nonvolatile memory cell may further include a transistor formed within the semi-conductive substrate. Preferably, the transistor includes a first part, a second part, and a third part. The first part may include a first junction region and a first charge trapping layer on the top surface of the protruding element. The second part may include a second junction region and a second charge trapping layer arranged on the planar top surface of the protruding element. The third part may have a gate electrode and a gate dielectric layer arranged at least partially on the sidewalls of the protruding element. The gate electrode is preferably overlaid to the first charge trapping layer and the second charge trapping layer.

Yet another embodiment of the invention provides a method for fabricating a nonvolatile memory cell. A charge trapping layer is conformably deposited on a surface of a semi-conductive substrate. A mask layer is deposited on the charge trapping layer. The mask layer is patterned to form structural elements of the mask layer on said charge trapping layer. The structural elements are arranged substantially parallel to each other at a predetermined distance. The charge trapping layer is etched between the structural elements of the mask layer. The semiconductor substrate can then be etched to form recesses between the structural elements of the mask layer. Each of the recesses has substantially vertical sidewalls and a bottom surface in order to define fins having a top surface as protruding elements of said semiconductor wafer. A dielectric layer is deposited on the bottom surface of the recesses between the fins. The dielectric layer is arranged in a region between the bottom surface and a top side of the structural elements. The structural elements of the mask layer are partially removed in regions above the top surface of the protruding elements. The dielectric layer is recessed so that the dielectric layer is arranged in a region between the bottom surface up to a height below the top surface of the protruding elements. A dielectric liner is deposited and arranged in the regions above the top surface of the protruding elements and forms a gate dielectric on the planar top surface and the sidewalls of the protruding elements. A conductive layer is deposited on the dielectric liner in order to define a gate line arranged substantially perpendicular to the protruding elements. The structural elements of the mask layer are removed and the dielectric liner is partially removed above the charge trapping layer. A further conductive layer is deposited on the side walls of the gate lines above the charge trapping layer. The charge trapping layer may be patterned using the further conductive layer and the gate lines as a mask. A spacer dielectric layer is deposited on the side walls of the further conductive layer and the patterned charge trapping layer. An implantation is performed in the top surfaces of the protruding elements to define source/drain-regions using the spacer dielectric layer as a mask.

Yet another embodiment provides a method for fabricating a nonvolatile memory. The method preferably comprises providing a semiconductor wafer, the semiconductor wafer having a semi-conductive substrate. The method may also comprise conformably depositing a charge trapping layer on a surface of the semi-conductive substrate and depositing a mask layer on the charge trapping layer. The mask layer is patterned to form a plurality of structural elements of the mask layer on the charge trapping layer. Preferably, the plurality of structural elements are substantially parallel to each other at a predetermined distance. The method may further include etching the charge trapping layer between the plurality of structural elements of the mask layer and also etching the semiconductor wafer to form a plurality of recesses between the structural elements of the mask layer. Preferably, each of the recesses have substantially vertical sidewalls and a substantially planar bottom surface in order to define plurality of fins having a top surface as protruding elements of the semiconductor wafer. A dielectric layer is deposited on the bottom surface of the plurality of recesses between the fins. Preferably, the dielectric layer is formed in a respective region between the bottom surface and a top side of the structural elements. The method may further comprise partially removing the structural elements of the mask layer in regions above the top surface of the protruding elements and recessing the dielectric layer. Preferably, the dielectric layer is formed in a respective region between the bottom surface up to a height below the top surface of the protruding elements. The method may also include forming a dielectric liner in each of the regions above the top surface of the protruding elements. A gate dielectric is formed on the planar top surface and the sidewalls of the protruding elements. Included further is depositing a conductive layer on each of the dielectric liner in order to define a plurality of gate lines arranged substantially perpendicular to the protruding elements. The method may also include removing the structural elements of the mask layer, partially removing the dielectric liner above the charge trapping layer for each of the regions, and depositing a further conductive layer on the side walls of each of the gate line above the charge trapping layer. The charge trapping layer may be patterned using the further conductive layer and the gate lines as a mask. The method may also include depositing a spacer dielectric layer on the side walls of each of the further conductive layer and the patterned charge trapping layer, and implanting the top surfaces of the protruding elements to define a plurality of source/drain-regions using the spacer dielectric layer as a mask.

Still another embodiment provides a nonvolatile memory cell, comprising: a semiconductor wafer having a protruding element forming a fin, the fin having a top surface, and a FinFET transistor arranged on the fin. A first charge trapping layer is formed on the top surface of the fin. The nonvolatile memory cell preferably further comprises a second charge trapping layer on the planar top surface of the fin, wherein the FinFET transistor further comprises a gate electrode and a gate dielectric layer at least partially on sidewalls of the fin. Preferably, the gate electrode connects to the first charge trapping layer and the second charge trapping layer.

Another embodiment provides a method for fabricating a nonvolatile memory cell. The method comprises the steps of: providing a semiconductor wafer, the semiconductor wafer having a semi-conductive substrate. The method also comprises conformably depositing a charge trapping layer on a surface of the semi-conductive substrate and a mask layer on the charge trapping layer. The mask layer is patterned to form structural elements of the mask layer on the charge trapping layer. The structural elements are preferably substantially parallel to each other at a predetermined distance. The method may also comprise etching the charge trapping layer between the structural elements of the mask layer and etching the semiconductor wafer to form recesses between the structural elements of the mask layer. Preferably, each of the recesses have substantially vertical sidewalls and a substantially planar bottom surface in order to define protruding elements having a top surface. A dielectric layer is deposited on the bottom surface of the recesses between the fins. Preferably, the dielectric layer is formed in a region between the bottom surface and a top side of the structural elements. The method may further comprise removing the structural elements of the mask layer, conformably depositing a further mask layer on the semiconductor wafer, and arranging a patterned resist layer on the further mask layer to form openings above the protruding elements. The method may also comprise etching the charge trapping layer and the further mask layer within the openings and removing the patterned resist layer. The dielectric layer is recessed by etching the dielectric layer and the protruding elements. Preferably, the dielectric layer is formed in a region between the bottom surface up to a predetermined height below the top surface of the protruding elements. The method also includes forming a groove within the protruding elements ranging from the planar top surface to the predetermined height. A dielectric liner is formed on a bottom surface of the groove and on sidewalls of the groove and on sidewalls of the patterned charge trapping layer. Preferably, the dielectric liner forms a gate dielectric. A conductive layer is deposited on the dielectric liner in order to define a gate line substantially perpendicular to the protruding elements. The further mask layer is removed. A further conductive layer is deposited on the side walls of the gate lines above the charge trapping layer. The charge trapping layer is patterned using the further conductive layer and the gate lines as a mask. The method may also include depositing a further dielectric liner on the semiconductor wafer, and implanting the top surfaces of the protruding elements to define source/drain-regions outside the gate lines and the further conductive layer.

Yet another embodiment provides a method for fabricating a nonvolatile memory. The method comprises the steps of providing a semiconductor wafer, the semiconductor wafer having a semi-conductive substrate. Conformably deposited is a charge trapping layer on a surface of the semi-conductive substrate and a mask layer on the charge trapping layer. The mask layer is patterned to form a plurality of structural elements of the mask layer on the charge trapping layer. Preferably, the plurality of structural elements are substantially parallel to each other at a predetermined distance. The method may further include etching the charge trapping layer between the plurality of structural elements of the mask layer. Preferably also etched is the semiconductor wafer to form a plurality of recesses between the structural elements of the mask layer, wherein each of the recesses have substantially vertical sidewalls and substantially planar bottom surfaces in order to define a plurality of protruding elements having a top surface. The method may also include depositing a dielectric layer on each of the bottom surface of the recesses between the fins. The dielectric layer is preferably formed in a respective region between the bottom surface and a top side of the structural elements. The method preferably further includes removing the structural elements of the mask layer. The method may further comprise conformably depositing a further mask layer on the semiconductor wafer and arranging a patterned resist layer on the further mask layer to form a plurality of openings above the protruding elements. The method may include etching the charge trapping layer and the further mask layer within the plurality of openings and removing the patterned resist layer. The method may also include etching the dielectric layer and the protruding elements to recess the dielectric layer. The dielectric layer is preferably formed in a respective region between the bottom surface up to a predetermined height below the top surface of the protruding elements. Included also is forming a plurality of grooves within the protruding elements ranging from the planar top surface to the predetermined height. The method may also comprise forming a dielectric liner on a bottom surface of the plurality of grooves and on sidewalls of the plurality of grooves and on sidewalls of the patterned charge trapping layer. Preferably, the dielectric liner forms a gate dielectric. The method may also include depositing a conductive layer on the dielectric liner in order to define a plurality of gate lines arranged substantially perpendicular to the protruding elements. The method may also include removing the further mask layer, depositing a further conductive layer on the side walls of the gate lines above the charge trapping layer, patterning the charge trapping layer using the further conductive layer and the plurality of gate lines as a mask. The method may also include depositing a further dielectric liner on the semiconductor wafer, and implanting the top surfaces of the protruding elements to define a plurality of source/drain-regions outside the gate lines and the further conductive layer.

Yet another embodiment provides a nonvolatile memory cell, comprising a semiconductor wafer having a protruding element, the protruding element having a top surface. Au-shaped transistor may be formed within the protruding element, and a first charge trapping layer formed on the top surface of the protruding element. The nonvolatile memory cell may also comprise a second charge trapping layer on the planar top surface of the protruding element. Preferably, the u-shaped transistor comprises a gate electrode and a gate dielectric layer on sidewalls of a groove within the protruding element. The gate electrode may connect the first charge trapping layer and the second charge trapping layer.

### BRIEF DESCRIPTION OF THE DRAWINGS

The above features of the present invention will be more clearly understood from consideration of the following descriptions in connection with accompanying drawings in which:

FIG. 1 schematically illustrates a plurality of memory cells in a top view according to an embodiment of the invention;

FIG. 2A schematically illustrates a memory cell in a perspective side view according to an embodiment of the invention;

FIG. 2B schematically illustrates a memory cell in a further perspective side view according to an embodiment of the invention;

FIG. 2C shows a source current vs. drain voltage diagram when using the memory cell to an embodiment of the invention;

FIG. 3A schematically illustrates a memory cell in a perspective side view according to a further embodiment of the invention;

FIG. 3B schematically illustrates a memory cell in a further perspective side view according to a further embodiment of the invention;

FIG. 3C shows a source current vs. drain voltage diagram when using the memory cell to a further embodiment of the invention;

FIGS. 4A-4T schematically illustrate a memory cell in a side view when applying the method steps according to an embodiment of the invention; and

FIGS. 5A-5E schematically illustrate a memory cell in a side view when applying the method steps according to an embodiment of the invention.

### DETAILED DESCRIPTION OF ILLUSTRATIVE EMBODIMENTS

A presently preferred embodiment of the method for fabricating non-volatile memory cells and non-volatile memory cell according to the invention is discussed in detail below. It is appreciated, however, that the present invention provides many applicable inventive concepts that can be embodied in a wide variety of specific contexts. The specific embodiments discussed are merely illustrative of specific ways to apply the method and the memory cell of the invention, and do not limit the scope of the invention.

In the following, embodiments of the method for fabricating non-volatile memory cells and non-volatile memory cells are described with respect to NROM memories having a plurality of non-volatile memory cells.

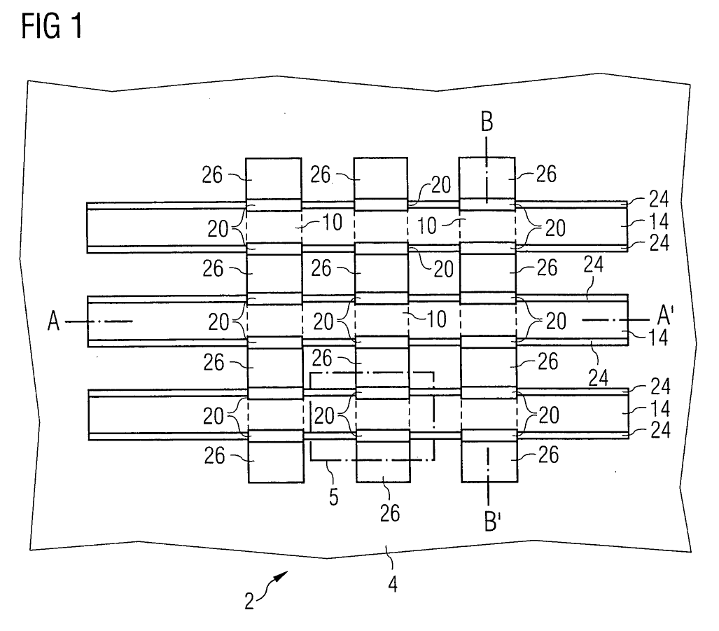

With respect to FIG. 1, a general layout of non-volatile memory cells is shown in a top view. It should be appreciated that FIG. 1 merely serves as an illustration of fabricating non-volatile memory cells, i.e., the individual components shown in FIG. 1 are not true to scale.

The stacked non-volatile memory cells are arranged on a semiconductor wafer 2 having a substrate 4. In particular memory cells 5 are arranged on protruding elements 10 being formed on the substrate 4. In FIG. 1, three protruding elements 10 are shown which are arranged substantially parallel to each other. Preferably, the protruding elements 10 have a height of about 200 nm or less. They are preferably spaced about 200 nm or less apart, although other heights and spacings are possible. In a direction perpendicular to the orientation of the protruding elements 10, word lines 14 are arranged serving as selection lines for selecting a certain memory cell 5. As shown in FIG. 1, three word lines 14 are arranged on top of the three protruding elements 10. A person skilled in the art knows, however, that a non-volatile memory comprises many more memory cells, to form a 512 Mb, a 1 Gb, or even larger memory.

The word lines 14 can be connected to a readout circuit (not shown) thus enabling individual memory cells to be selected and read out by external circuitry. As this part of the circuit is not part of the invention, it will not be discussed in detail. It should be mentioned that external circuitry is known to a person skilled in the art.

As shown in FIG. 1, the memory cell is arranged on the semiconductor wafer 2 with the semi-conductive substrate 4. A patterned charge trapping layer 20 is formed on the protruding elements 10. The word lines 14 have side walls which are covered by a conductive layer and a spacer oxide layer (not shown in FIG. 1). The conductive layer, also called sidewall spacer and denoted with reference numeral 24 in FIG. 1, covers the patterned charge trapping layer 20. On the protruding elements 10, source/drain-regions 26 are formed outside the word line 14 and the spacer oxide layer next to the patterned charge trapping layer 20.

In order to connect the source/drain-regions 26, a metallization layer can be used for employing a local interconnect scheme, as for example disclosed in J. Willer et al., “110 nm NROM Technology for Code and Data Flash Products”, IEEE Digest of technical Papers, 2004 Symposium on VLSI Technology, pages 76 -77, which is incorporated herein by reference.

The resulting memory cell 5 therefore has two source/drain-regions 26, which are further connected to the word line 14. The charge trapping layer 20, i.e. an oxide/nitride/oxide-layer or aluminum nitride layer stack, provides non-volatile storage properties. The charge trapping layer 20 is arranged at the crossing regions of the word lines 14 and the active area, i.e. below the side wall spacer 24.

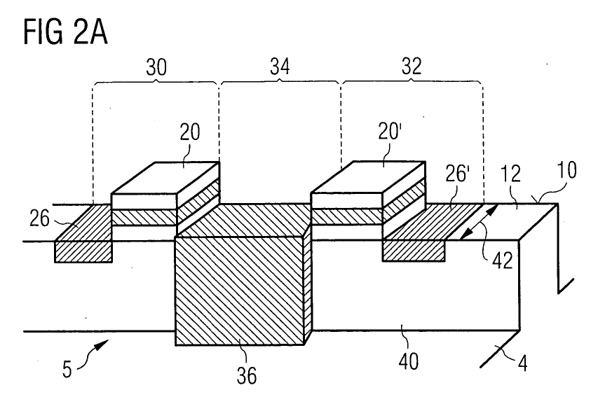

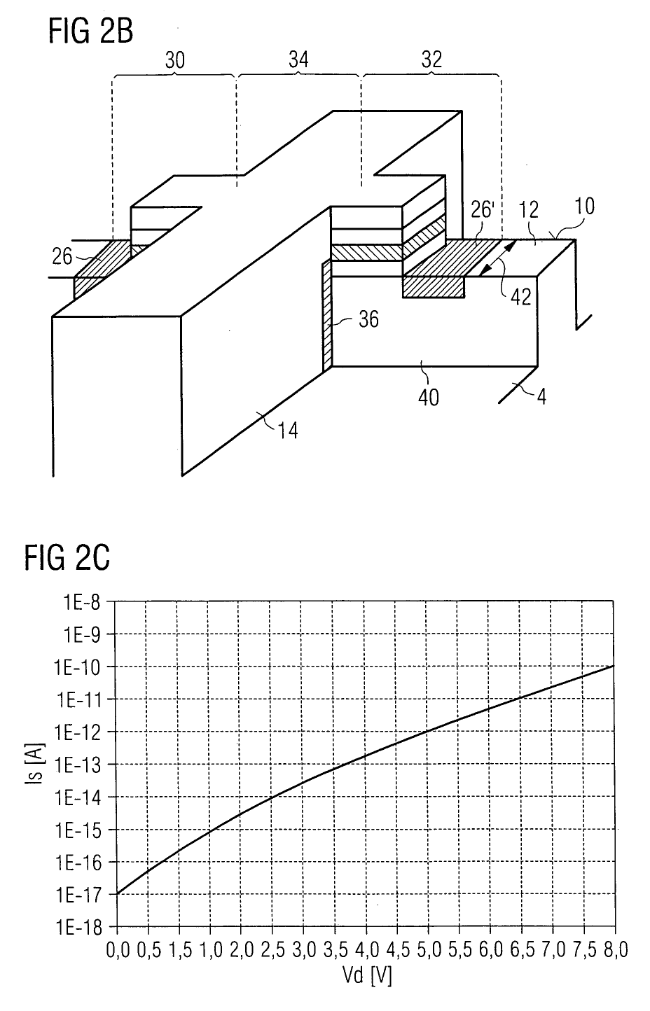

Referring now to FIG. 2A, a first embodiment of the memory cell 5 is shown. FIG. 2A shows the nonvolatile memory cell 5 in a perspective side view. In order to illustrate the inventive concept according to this embodiment, only a partially fabricated memory cell is shown.

The memory cell 5 is arranged on the semiconductor wafer including the semi-conductive substrate 4. The semi-conductive substrate is structured to form the protruding element 10. The protruding element 10 has top surface 12, which is shown in FIG. 2A being substantially planar.

The transistor of the memory cell 5 is formed within the protruding element 10. The transistor can be schematically subdivided into a first part 30, a second part 32, and a third part 34.

The first part 30 of the transistor includes a first junction region forming the first source/drain-region 26. Furthermore, the first part includes a first charge trapping layer 20 that is arranged on the top surface 12 of the protruding element 10 adjacent to or partially overlapping to the first junction region 26.

The second part 32 of the transistor includes a second junction region forming the second source/drain-region 26′. In addition, the second part 32 includes a second charge trapping layer 20′ that is arranged on the top surface 12 of the protruding element 10 adjacent to or partially overlapping to the second junction region. The second part 32 is oriented such that the first charge trapping layer 20 and the second charge trapping layer 20′ face each other. The first part 30 and the second part 32 are arranged at a certain distance on the protruding element 10, leaving space in-between.

The third part 34 is arranged in the space between the first part 30 and the second part 32. The third part 34 of the transistor includes a gate dielectric layer 36. The gate dielectric layer is arranged on the sidewalls 40 of the protruding element 10 and the top surface 12 of the protruding element 10. Above the gate dielectric layer 36 a gate electrode can be arranged that is capable of connecting to the first charge trapping layer 20 and the second charge trapping layer 20′.

As shown in FIG. 2A, the protruding element 10 is arranged as a fin being arranged perpendicular to the surface of the semi-conductive wafer 2. The protruding element includes substantially vertical sidewalls 40. The protruding element 10 or fin has a thickness 42 along the top surface 12 that is usually defined by a minimum resolution F of a photolithographic projection apparatus during fabrication. Using for e.g., an isotropic etching step for fabricating the fin, the thickness 42 can be less than the minimum resolution F, for example approximately half of the minimum resolution F.

Optionally (not shown in FIG. 2A), a third charge trapping layer can be arranged on the planar top surface 12 of within the third part 34 thus forming a continuous charge trapping layer from the first junction region 26 to the second junction region 26′.

Accordingly, a FinFET (wherein FinFET is an abbreviation for Field Effect Transistor on a FIN) is formed within the semi-conductive substrate 4. The FinFET transistor is attached to the first charge trapping layer 20 and the second charge trapping layer 20′ thus providing non-volatile storage capabilities.

As shown in FIG. 2B, the first part 30 of the transistor includes a first gate region 14′. The second part 32 includes a second gate region 14″. Both, the first gate region 14′ and the second gate region 14″ are part of the word line 14. Preferably, the word line 14 together with the first gate region 14′ and the second gate region 14″ overlay the first charge trapping layer 20 and the second charge trapping layer 20′.

During programming, hot electrons are injected in either the first charge trapping layer 20 or the second charge trapping layer 20′. As the gate dielectric layer 36 extends below the top surface 12 of the protruding element 10, the electrical path between first junction region 26 to the second junction region 26′ is enlarged thus reducing punch through.

Referring now to FIG. 2C, a simulation result is shown that underlines the reduced punch through effect. In FIG. 2B, a FinFET transistor having a fin with 20 nm thickness, a gate length (i.e. the dimension of the third part along the fin) of 50 nm and a sidewall height of the fin of 125 nm is simulated. As a result, source current is plotted against the drain voltage for a fixed gate voltage of 0 V. As can been seen from FIG. 2C, the punch through current remains below 10⁻¹⁰ μA.

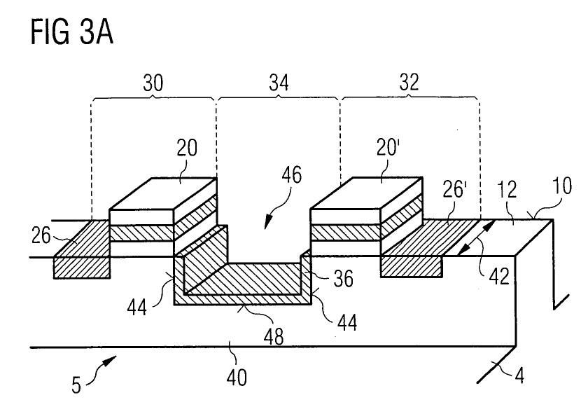

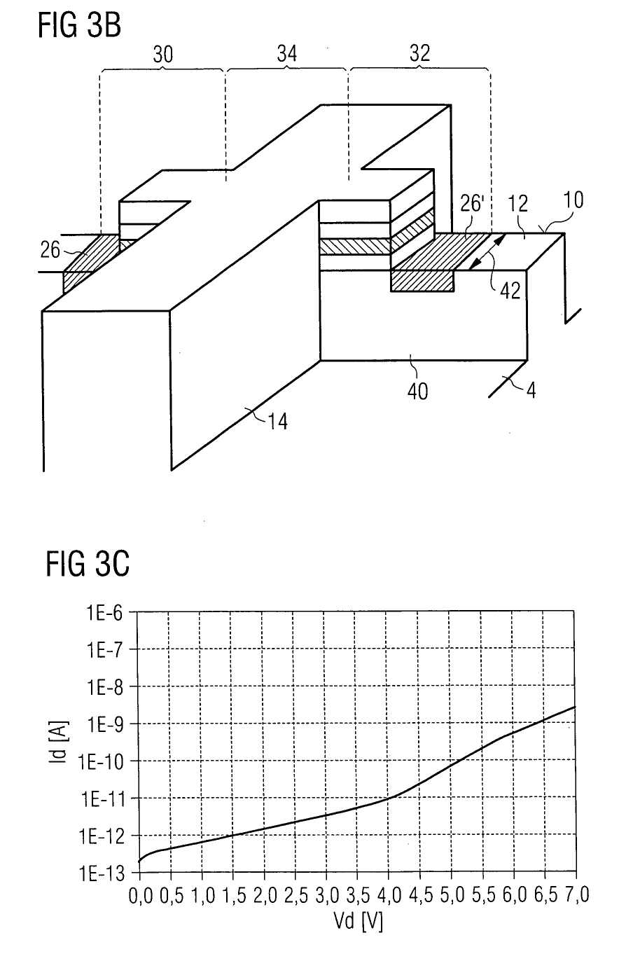

Referring now to FIG. 3A, a second embodiment of the memory cell 5 is shown. FIG. 3A shows the nonvolatile memory cell 10 in a perspective side view. Again, only a partially fabricated memory cell is shown in order to illustrate the inventive concept according to the second embodiment.

The memory cell 5 is arranged on the semiconductor wafer including the semi-conductive substrate 4. The semi-conductive substrate 4 is again structured to form the protruding element 10 including the e.g., substantially flat top surface 12.

As shown in FIG. 3A, the protruding element 10 is arranged perpendicular to the surface of the semi-conductive wafer 2. The protruding element 10 includes substantially vertical sidewalls 40. The protruding element 10 has a thickness 42 along the top surface 12 that is usually defined by a minimum resolution F of a photolithographic projection apparatus during fabrication.

The transistor of the memory cell is formed within the protruding element 10. Again, the transistor can be subdivided into the first part 30, the second part 32, and the third part 34.

The first part 30 of the transistor includes the first junction region 26 forming the first source/drain-region. Furthermore, the first part 30 includes the first charge trapping layer 20 that is arranged on the top surface 12 of the protruding element 10 adjacent to or partially overlapping to the first junction region 26.

The second part 32 of the transistor includes the second junction region 26′ forming the second source/drain-region. In addition, the second part 32 includes the second charge trapping layer 20′ that is arranged on the top surface 12 of the protruding element 10 adjacent to or partially overlapping to the second junction region 26′. The second part 32 is oriented such that the first charge trapping layer 20 and the second charge trapping layer 20′ face each other. The first part 30 and the second part 32 are arranged at a certain distance on the protruding element 10, leaving space in-between.

The third part 34 is arranged in the space between the first part 30 and the second part 32.

The third part 34 of the transistor includes the gate dielectric layer 36. Again, the gate dielectric layer 36 is arranged on sidewalls 44 of the protruding element 10, wherein in this embodiment the sidewalls are formed by a groove 46 in the protruding element 10.

As shown in FIG. 3A, the protruding element 10 further includes the groove 46, i.e., a region with completely removed semi-conductive substrate 5 ranging from the top surface 12 to a certain depth. The groove 46 is arranged within the third part 34 of the transistor between the first patterned charge trapping layer 20 and the second patterned charge trapping layer 20′.

The gate dielectric layer 36 is arranged on the sidewalls 44 of the groove 46 and on the bottom surface 48 of the groove 46. The gate dielectric layer 36 is covered by the gate electrode (not shown in FIG. 3A). The gate electrode is capable of controlling the first charge trapping layer 20 and the second charge trapping layer 20′.

As shown in FIG. 3A, the groove 46 of the protruding element 10 has bottom 48 and lateral surfaces 44 being substantially perpendicular to each other. It is, however, also conceivable to arrange the groove 46 with rounded corners between the bottom surface and the lateral surfaces.

Preferably, a u-shaped transistor or U-transistor is formed within the semi-conductive substrate 4. The U-transistor is attached to the first charge trapping layer 20 and the second charge trapping layer 20′ thus providing non-volatile storage capabilities.

As shown in FIG. 3B, the first part 30 of the transistor includes a first gate region 14′. The second part 32 includes a second gate region 14″. Both, the first gate region 14′ and the second gate region 14″ are part of the word line 14. Preferably, the word line 14 together with the first gate region 14′ and the second gate region 14″ overlay the first charge trapping layer 20 and the second charge trapping layer 20′.

As discussed above, hot electrons are injected during programming in either the first charge trapping layer 20 or the second charge trapping layer 20′. As the gate dielectric layer 36 extends below the top surface 12 of the protruding element 10, the electrical path between first junction region 26 to the second junction region 26′ is enlarged thus reducing punch through.

Referring now to FIG. 3C, a simulation result is shown that underlines the reduced punch through effect. In FIG. 3B, a U-transistor having a groove with 40 nm with and 120 nm depth is simulated. As a result, the source current is plotted against the drain voltage for a fixed gate voltage of 0 V. As can been seen from FIG. 3C, the punch through current remains below 10⁻⁹ μA.

In the following, a method for fabricating the memory cell according to the first embodiment is described. The following method steps also further illustrate possible materials for the individual components and respective geometrical characteristics.

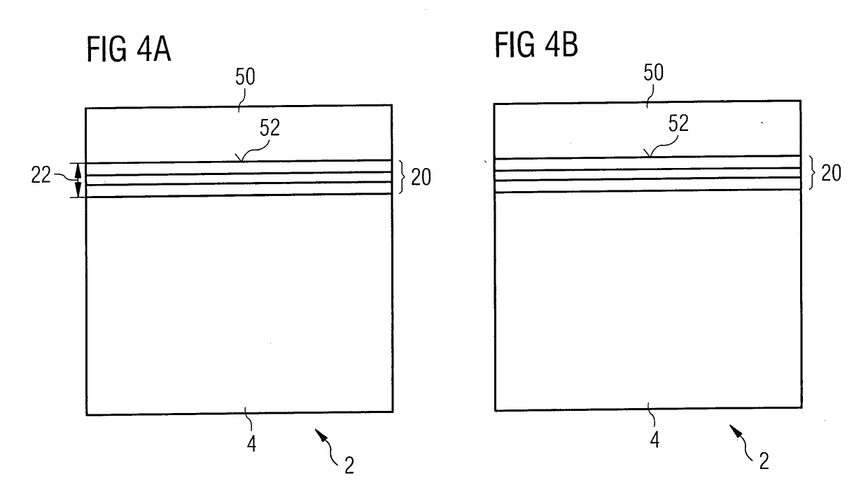

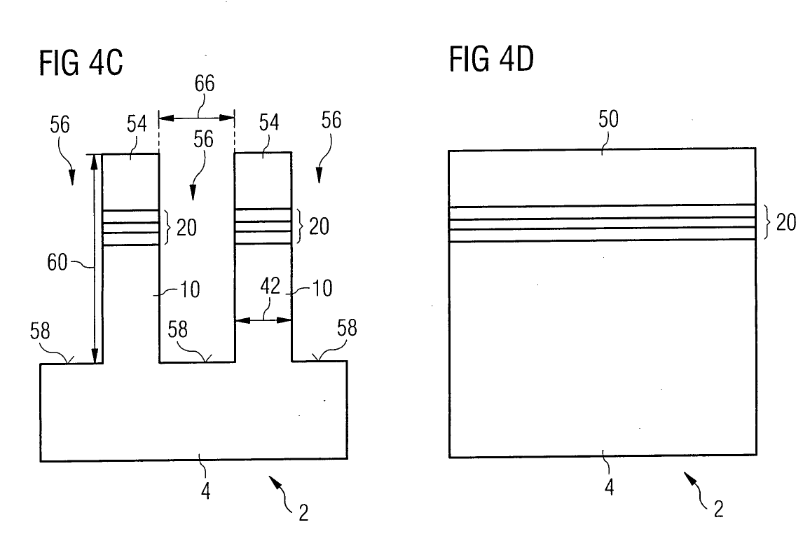

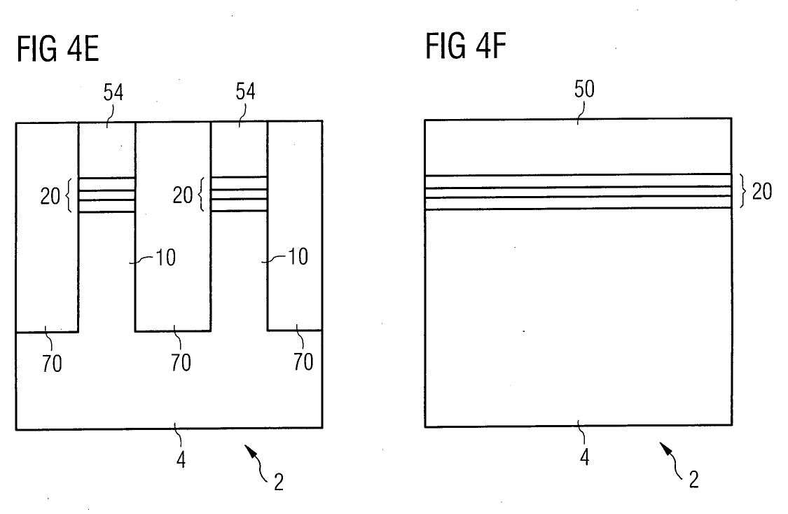

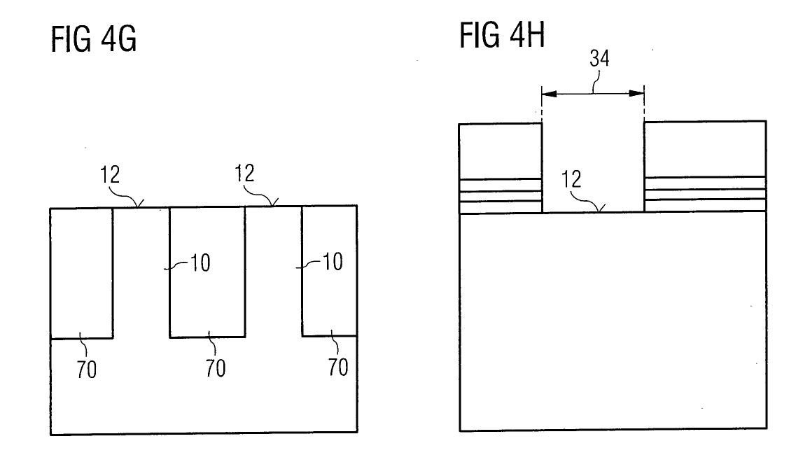

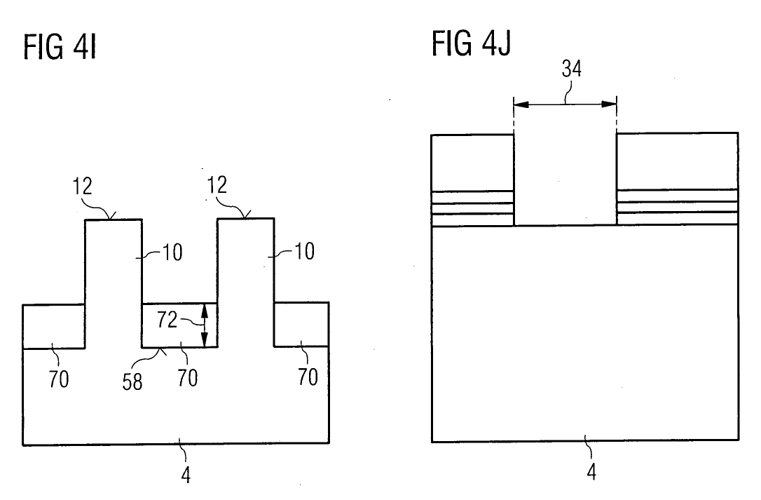

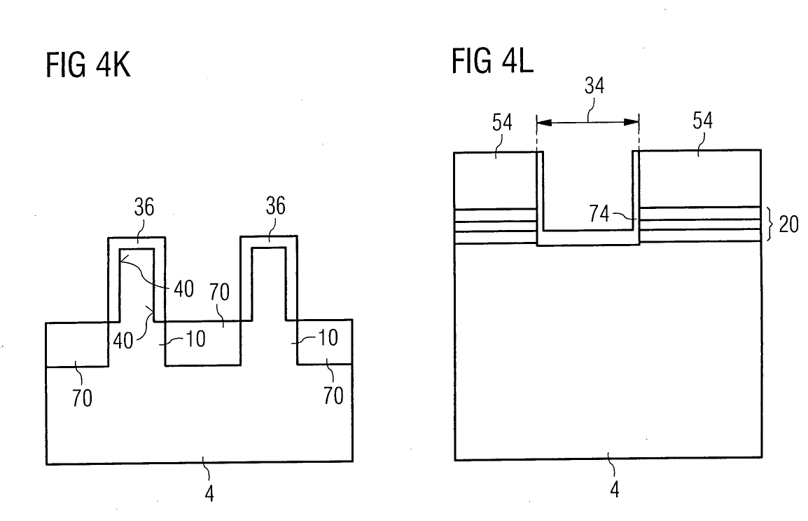

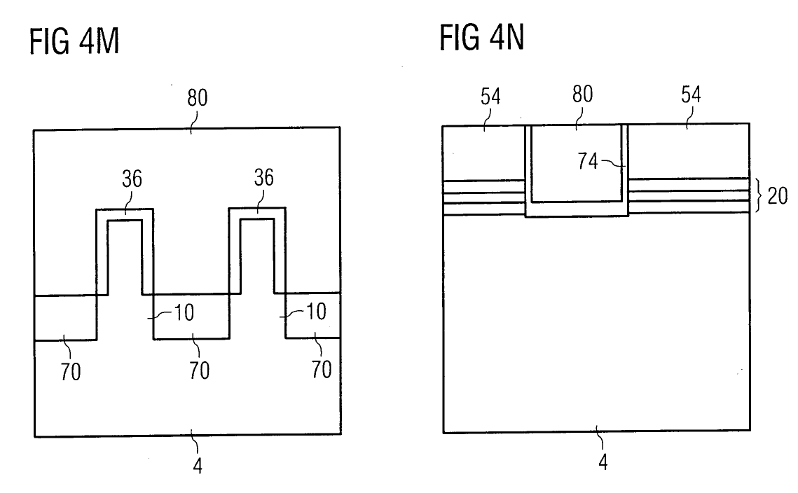

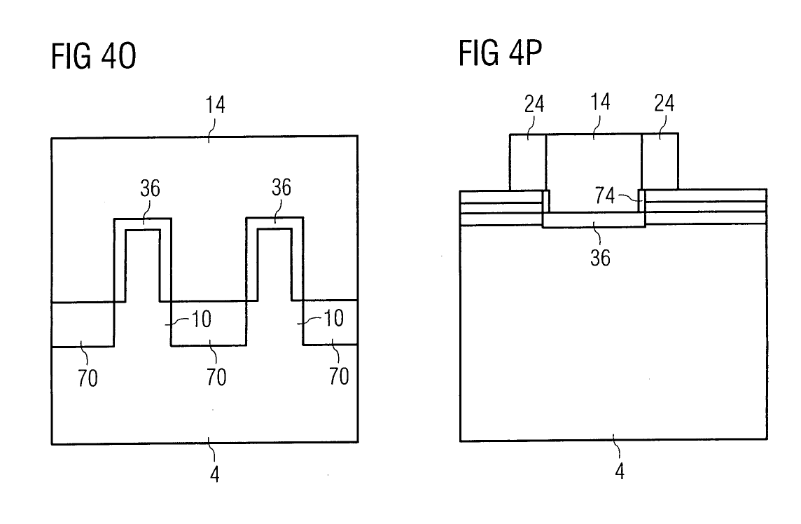

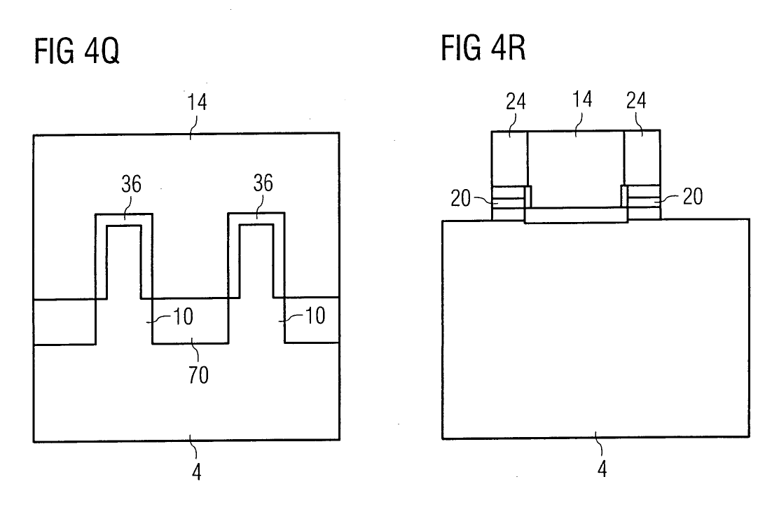

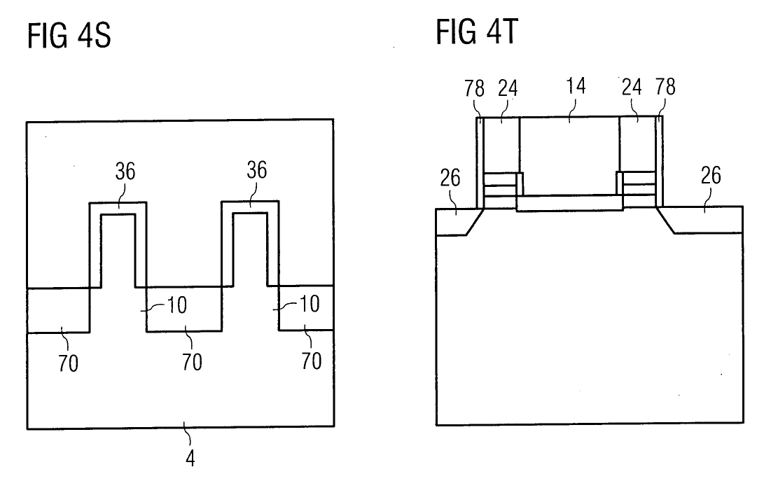

Referring now to FIG. 4A and 4B, a method for forming non-volatile memory cells is illustrated.

In FIG. 4A, the semiconductor wafer 2 is shown in a side view. The side view of FIG. 4A (and also each of the following FIGS. 4C, 4E, 4G-4S) are side views along in plane perpendicular to the surface of the semiconductor wafer 2. The cross sectional view follows the line A to A′, as indicated in FIG. 1.

In FIG. 4B, the semiconductor wafer 2 is shown in a side view. The side view of FIG. 4B (and also the following FIGS. 4D, 4F, 4H-4T) are side views along in plane perpendicular to the surface of semiconductor wafer 2 and to the plane of FIG. 4A. The cross sectional view follows the line B to B′ of FIG. 1.

The semiconductor wafer 2 includes the semi-conductive substrate 4. As an example, the semiconductor wafer 2 is provided as a silicon wafer, which comprises a p-doped silicon substrate as semi-conductive substrate 4.

As shown in FIG. 4A and 4B, processing continues by conformably depositing a charge trapping layer 20 on the semiconductor wafer 2. As an example, depositing the charge trapping layer 20 includes forming an oxide/nitride/oxide-layer stack. The oxide/nitride/oxide-layer stack can have a thickness 22 of less than about 50 nm, preferably in a range between about 5 nm and 30 nm.

In a next step, a mask layer 50 is deposited on the surface of the charge trapping layer 20. As an example, the step of depositing the mask layer 50 on the surface 52 of charge trapping layer 20 can be employed by depositing a silicon nitride layer. In general, mask layer 50 should have a high etching resistance against the materials of the semi-conductive substrate 4 and the charge trapping layer 20.

In a next step, the mask layer 50 is lithographically patterned, to form structural elements 54 of the mask layer 50 on the surface 52 of the charge trapping layer 20.

The patterning of the mask layer 50 comprises depositing a resist layer on the surface of the mask layer 50 and lithographically patterning the resist layer to form a patterned resist layer. After removing the mask layer 50 outside the patterned resist layer by etching, the patterned resist layer can be removed.

Referring now to FIGS. 4C and 4D, the structural elements 54 of the mask layer 50 are used as an etch mask in order to etch the semi conductive substrate 4 of semiconductor wafer 2. This etching step is performed selective to the patterned mask layer 50 by employing an anisotropic etching step.

As a result recesses 56 are formed in the semiconductor wafer 2 between the structural elements 54 of the mask layer 50, as shown in FIG. 4C. Each of the recesses 56 have a bottom surface 58. The semiconductor wafer 2 is etched up to a depth 60 extending into the semi-conductive substrate 4. Accordingly, fins or protruding elements 10 are defined being comprised of the semi-conductive substrate 4, as shown in FIG. 4C.

In summary, etching of the semiconductor wafer 2 creates recesses 56 and corresponding protruding fins 10 being formed by the semi-conductive substrate 4 in an embodiment of the invention. The width 66 of the recesses 16 and the width 42 of the corresponding fins 10 are defined by the lithographic patterning step of the mask layer 50. Accordingly, the size of fin 10 is preferably defined by a minimum resolution F of a photolithographic projection apparatus used for lithographic patterning the mask layer 50.

It is, however, also conceivable to form the corresponding fins 10 smaller then the minimum resolution F of the photolithographic projection apparatus, e.g., by employing an isotropic etching step that further thins the structural elements 54. In the direction along the protruding element 10, the mask layer 50 is still covering the top side of the protruding element 10. Accordingly, FIG. 4D remains unaltered as compared to FIG. 4B.

Referring now to FIGS. 4E and 4F, the next processing step is shown. A dielectric layer 70 is deposited on the bottom surface 58 of the recesses 56. Depositing the dielectric layer 70 on the bottom surface 58 of the recesses 56 may be performed in the following way. First, the dielectric layer 70 is conformably deposited as a silicon dioxide layer. The dielectric layer 70 covers the recesses 56 and the structural elements 54 of the mask layer 50.

In a chemical mechanical polishing step, the dielectric layer 70 is removed from the top side of the hard mask 50. In the direction along the protruding element 10, the mask layer 50 still protects the top side of the protruding element 10. Accordingly, FIG. 4E preferably remains unchanged as compared to FIG. 4B.

Referring now to FIGS. 4G and 4H, the structural elements 54 of the mask layer 50 are partially removed, for example in a further lithographic patterning step using a further patterned resist layer (not shown in FIGS. 4G and 4H).

Optionally, the further patterned resist layer can be used as an implantation mask for adjusting electrical properties of the transistor of the memory cell 5.

Using the further patterned resist layer, the mask layer 50 and the charge trapping layer 20 are removed in the third part 34 of the memory cell, i.e., in regions above the top surface 12 of the protruding elements 10. These regions are arranged substantially perpendicular to the orientation of the protruding elements 10, as shown in FIG. 4G and FIG. 4H.

Referring now to FIGS. 4I and 4J, the dielectric layer 70 is reduced in thickness in order to be arranged below the top surface 12 of the protruding element 10. The dielectric layer 70 in the recess 56 serves later as a shallow trench isolation. As a result, the dielectric layer 70 is recessed up to a thickness 72 on the surface 58 of the bottom surface. The step of recessing the dielectric layer 30 may comprise etching.

Referring now to FIGS. 4K and 4L, a dielectric liner 74 is formed. The dielectric liner 74 is arranged in the region above the top surface 12 of the protruding elements 10. Within the third part 34, the dielectric liner 74 forms the gate dielectric layer 36 on the planar top surface 12 and the sidewalls 40 of the protruding element 10, see also FIG. 2A. In addition, the dielectric liner 74 covers the sidewalls of the structural elements 54 and the patterned charge trapping layer 20, as shown in FIG. 4L.

Forming the dielectric liner 74 may comprise oxidizing the substrate 4 in order to create silicon dioxide liner. As an alternative, silicon dioxide can also be formed by the reaction of N₂0 and dichlorosilane (SiH₂Cl₂) known as high temperature oxidation (HTO). The properties of this silicon dioxide are comparable to the thermal oxidation process. Preferred HTO processes, however, do not consume the silicon substrate 4.

Referring now to FIGS. 4M and 4N, a conductive layer 80 is formed on the dielectric liner 74. The conductive layer 80 preferably defines a gate line or word line 14 being arranged substantially perpendicular to the protruding element 10. The conductive layer 80 is structured using a CMP-process after deposition.

In order to enhance the conductivity of word lines 14, the step of depositing a conductive layer 80 may be followed by conformably depositing a metal containing layer on the surface of the conductive layer 80 (not shown in FIG. 4M). The metal containing layer comprises, e.g., tungsten or tungsten silicide.

As shown in FIGS. 4O and 4P, the structural elements 54 of the mask layer 50 are removed, e.g. by employing a wet etching step. After this process step, the charge trapping layer is released. During this process step, the part of the dielectric liner 74, which extends beyond the surface of the charge trapping layer may also be removed. As a result, the dielectric liner 74, which also serves as a gate dielectric 36, isolates the word line 14 formed by conductive layer 70.

Furthermore, a further conductive layer is deposited on the side walls of the word line 14 above the charge trapping layer 20. The further conductive layer serves as a sidewall spacer 24, as shown in FIG. 1. The further conductive layer can be conformably deposited and afterwards lithographically patterned using a suitable resist mask to form the sidewall spacer 24.

The spacer dielectric layer can be formed as a poly silicon layer that is structured by a spacer process. The sidewall spacer 24 defines the first gate region 14′ and the second gate region 14″ overlaying the first charge trapping layer 20 and the second charge trapping layer 20′, as shown in FIG. 2B.

Referring now to FIGS. 4Q and 4R, the charge trapping layer is patterned using sidewall spacer 24 formed by the further conductive layer and the gate lines as a mask.

Referring now to FIGS. 4S and 4T, a spacer dielectric layer 78 is deposited on the side walls of the sidewall spacer 24 and the patterned charge trapping layer 20, e.g., as a silicon dioxide layer which has been lithographically patterned using a resist mask.

In a next step, source/drain-regions 26 for the FinFET are defined by implanting the surface 12 of the fins 10, as shown in FIG. 4S and 4T.

In further processing steps interconnecting metal layers are applied, as known in the art. The processing steps include depositing further dielectric layers, etching contact holes and applying the interconnecting wiring.

In the following, a method for fabricating the memory cell according to the second embodiment is described. The following method steps also further illustrate possible materials for the individual components and respective geometrical characteristics.

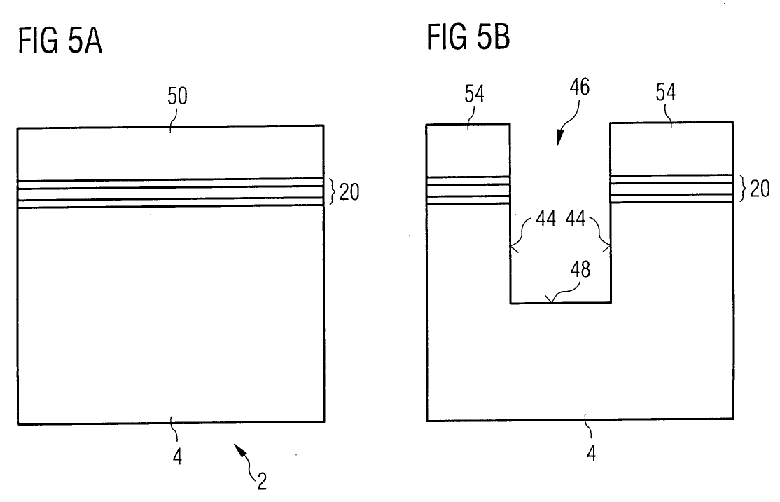

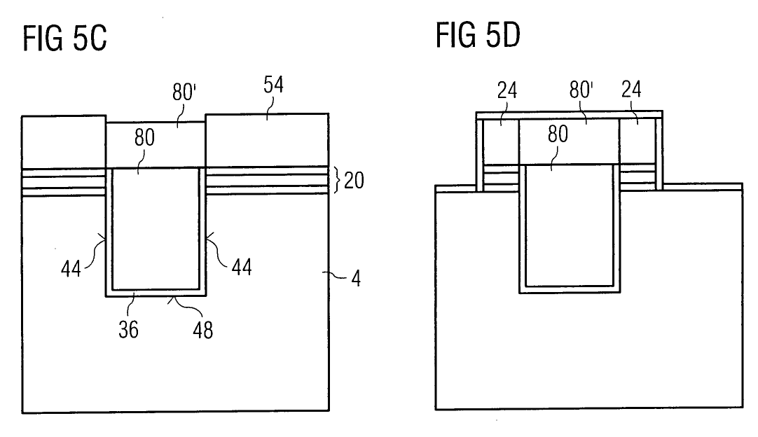

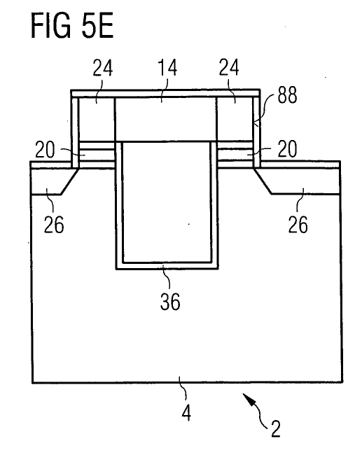

Referring now to FIG. 5A, a method for forming a non-volatile memory cell is illustrated.

In FIG. 5A, the semiconductor wafer 2 is shown in a side view. The side view of FIG. 5A (and also the following FIGS. 5B to 5E) are side views along in plane perpendicular to the surface of the semiconductor wafer 2. The cross sectional view follows the line B to B′, as indicated in FIG. 1.

As most of the processing in the direction A to A′ is preferably similar to what has been described with respect to FIGS. 4, the view along these lines has been omitted for simplicity. Accordingly, the following description refers to the description of FIGS. 4A to 4T as well, where appropriate.

The semiconductor wafer 2 includes the semi-conductive substrate 4. As an example, the semiconductor wafer 2 is provided as a silicon wafer, which comprises a p-doped silicon substrate as semi-conductive substrate 4.

As shown in FIG. 5A, processing continues by conformably depositing a charge trapping layer 20 on the semiconductor wafer 2. As an example, depositing the charge trapping layer 20 includes forming an oxide/nitride/oxide-layer stack. The oxide/nitride/oxide-layer stack may have a thickness 22 of less than about 50 nm, preferably in a range between about 5 nm and 30 nm.

In a next step, a mask layer 50 is deposited on the surface of the charge trapping layer 20. As an example, the step of depositing the mask layer 50 on the surface 52 of charge trapping layer 20 may comprise depositing a silicon nitride layer. In general, mask layer 50 should have a high etching resistance against the materials of the semi-conductive substrate 4 and the charge trapping layer 20.

In a next step, the mask layer 50 is lithographically patterned to form structural elements 54 of the mask layer 50 on the surface 52 of the charge trapping layer 20. In a first step, the structural elements 54 of the mask layer 50 are used to form protruding elements 10 (not shown in FIG. 5A) that will form the shallow trench isolation (STI) after deposition of oxide and CMP-process.

Next, the structural elements 54 of the mask layer 50 are removed, for example in the wet etching step. A further mask layer 50′ is deposited on the surface of the charge trapping layer 20. As an example, the step of depositing the further mask layer 50′ on the surface 52 of charge trapping layer 20 may comprise depositing a silicon nitride layer. The further mask layer 50′ is lithographically patterned to form further structural elements 54′.

The further structural elements 54′ of the further mask layer 50′ are used as an etch mask in order to etch the protruding elements. This etching step is performed selective to the patterned mask layer 50 by employing an anisotropic etching step.

As a result grooves 46 are formed in the protruding elements 10 of the semiconductor wafer 2 between the structural elements 54 of the mask layer 50, as shown in FIG. 5B. Each of the grooves 46 has a bottom surface 48 and sidewalls 44. In summary, etching of the semiconductor wafer 2 preferably creates grooves 46 within corresponding protruding elements 10 formed by the semi-conductive substrate 4.

Similar to the first embodiment, a dielectric layer 70 is deposited on the bottom surface 58 between the protruding elements 10 and recessed to form shallow trench isolation.

Using a patterned resist layer, the further mask layer 50′ is removed in the third part 34 of the memory cell, i.e. in regions above the top surface 12 of the protruding elements 10. These regions are arranged substantially perpendicular to the orientation of the protruding elements 10.

Optionally, the further patterned resist layer can be used as an implantation mask for adjusting electrical properties of the transistor of the memory cell 5.

Referring now to Figure 5C, a dielectric liner is formed. The dielectric liner is arranged on the side walls 44 and the bottom surface 48 of the grooves 46 of the protruding elements 10. Within the third part 34, the dielectric liner forms the gate dielectric layer 36, see also FIG. 3A.

Next, a conductive layer 80 is formed on the gate dielectric layer 36. The conductive layer 80 defines a gate line or word line 14 is substantially perpendicular to the protruding element 10.

In order to enhance the conductivity of word lines 14, the step of depositing a conductive layer 80 may be followed by conformably depositing a metal containing layer 80′ on the surface of the conductive layer 80. The metal containing layer 80′ comprises e.g. tungsten or tungsten silicide. Metal containing layer 80′ and conductive layer 80 are in the following commonly referred to as word line 14.

As shown in Figure 5D, the further structural elements 54 of the further mask layer 50 are removed, e.g., by employing a wet etching step. After this process step, a further conductive layer is deposited the side walls of the word line 14 above the charge trapping layer 20.

The further conductive layer serves as a sidewall spacer 24, as shown in FIG. 1. The further conductive layer can be conformably deposited and afterwards lithographically patterned using a suitable resist mask to form sidewall spacer 24. The spacer dielectric layer can be formed as a poly silicon layer and a spacer etch process.

The sidewall spacer 24 defines the first gate region 14′ and the second gate region 14″ overlaying the first charge trapping layer 20 and the second charge trapping layer 20′, as shown in FIG. 3B.

Next, the charge trapping layer is patterned using the sidewall spacer 24 formed by the further conductive layer and the word line 14 as a mask.

Referring now to FIG. 5E, a further dielectric liner 88 is deposited on the semiconductor wafer 2 and in a next step, source/drain-regions 26 for the transistor are defined by implanting the surface 12 of the fins 10, as shown in FIG. 4S and 4T.

In further processing steps interconnecting metal layers are applied, as known in the art. The processing steps include depositing further dielectric layers, etching contact holes and applying the interconnecting wiring.

Having described embodiments for methods for fabricating non-volatile memory cells and non-volatile memory cells, it is noted that modifications and variations can be made by persons skilled in the art in light of the above teachings. It is therefore understood that changes may be made in the particular embodiments of the invention disclosed that are within the scope and spirit of the invention as defined by the appended claims.

Having thus described the invention with the details and the particularity required by the patent laws, what is claimed and desired to be protected by Letters Patent is set forth in the appended claims.

What is claimed is:

1. A nonvolatile memory cell, comprising:
a semiconductor wafer, the semiconductor wafer having a semi-conductive substrate being structured to form at least one protruding element having a top surface; and
a transistor formed within the semi-conductive substrate, the transistor comprising a first part, a second part, and a third part, the first part comprising a first junction region and a first charge trapping layer arranged on the top surface of the protruding element, the second part comprising a second junction region and a second charge trapping layer being arranged on the top surface of the protruding element, and the third part having a gate electrode and a gate dielectric layer being arranged at least partially on sidewalls of the protruding element, the gate electrode being overlaid to the first charge trapping layer and the second charge trapping layer.

2. The memory cell according to claim 1, wherein the protruding element further comprises a groove ranging from the planar top surface and within the third part of the transistor to form the sidewalls.

3. The memory cell according to claim 2, wherein the groove within the protruding element is covered by the gate dielectric layer.

4. The memory cell according to claim 3, wherein the gate dielectric layer is covered by the gate electrode.

5. The memory cell according to claim 4, wherein the groove within the protruding element has a bottom surface and lateral surfaces substantially perpendicular to the bottom surface.

6. The memory cell according to claim 5, wherein the groove comprises rounded corners between the bottom surface and the lateral surfaces.

7. The memory cell according to claim 1, wherein the protruding element comprises a fin perpendicular to the surface of the semi-conductive wafer, the fin having substantially vertical sidewalls and a thickness along the top surface defined by a minimum resolution F of a photolithographic projection apparatus.

8. The memory cell according to claim 7, wherein the thickness along the top surface is less than the minimum resolution F.

9. The memory cell according to claim 7, wherein the thickness along the top surface is approximately half of the minimum resolution F.

10. The memory cell according to claim 1, wherein the gate dielectric layer is formed on the substantially vertical sidewalls of the protruding element and on the top surface within the third part.

11. The memory cell according to claim 10, wherein a third charge trapping layer is formed on the top surface of the protruding element within the third part.

12. A method for fabricating a nonvolatile memory cell, comprising the steps of:
providing a semiconductor wafer, the semiconductor wafer having a semi-conductive substrate;
conformably depositing a charge trapping layer on a surface of the semi-conductive substrate;
depositing a mask layer on the charge trapping layer;
patterning the mask layer to form structural elements of the mask layer on the charge trapping layer, the structural elements being arranged substantially parallel to each other at a predetermined distance;
etching the charge trapping layer between the structural elements of the mask layer;
etching the semiconductor wafer to form recesses between the structural elements of the mask layer, each of the recesses having substantially vertical sidewalls and a bottom surface in order to define fins having a top surface as protruding elements of the semiconductor wafer;
depositing an dielectric layer on the bottom surface of the recesses between the fins, the dielectric layer being arranged in a region between the bottom surface and a top side of the structural elements;
partially removing the structural elements of the mask layer in regions above the top surface of the protruding elements, the regions being arranged substantially perpendicular to the orientation of the protruding elements;
recessing the dielectric layer, the dielectric layer being arranged in a region between the bottom surface up to a height below the top surface of the protruding elements;
forming a dielectric liner, the dielectric liner being arranged in the regions above the top surface of the protruding elements and forming a gate dielectric layer on the planar top surface and the sidewalls of the protruding elements;
depositing a conductive layer on the dielectric liner in order to define a gate line being arranged substantially perpendicular to the protruding elements;
removing the structural elements of the mask layer;
partially removing the dielectric liner above the charge trapping layer;
depositing a further conductive layer on the side walls of the gate lines above the charge trapping layer;
patterning the charge trapping layer using the further conductive layer and the gate lines as a mask;
depositing a spacer dielectric layer on the side walls of the further conductive layer and the patterned charge trapping layer; and
implanting the top surfaces of the protruding elements to define source/drain-regions using the spacer dielectric layer as a mask.

13. The method according to claim 12, wherein the step of depositing a mask layer on the surface of the charge trapping layer comprises conformably depositing a nitride layer as the mask layer.

14. The method according to claim 13, wherein the step of patterning the mask layer comprises:
depositing a resist layer on the surface of the mask layer;
lithographically patterning the resist layer to form a patterned resist layer;
removing the mask layer outside the patterned resist layer by etching to form the structural elements of the mask layer; and
removing the patterned resist layer.

15. The method according to claim 12, wherein the step of etching the semiconductor wafer selective to the structural elements of the patterned mask layer comprises employing an anisotropic etching.

16. The method according to claim 15, wherein the anisotropic etching comprises reactive ion etching.

17. The method according to claim 12, wherein the step of depositing an dielectric layer on the bottom surface of the recesses comprises:
conformably depositing the dielectric layer as a silicon dioxide layer;
chemical mechanical polishing dielectric layer to remove the dielectric layer from the structural elements of the mask.

18. The method according to claim 12, wherein the step of recessing the dielectric layer comprises anisotropic etching the dielectric layer.

19. The method according to claim 18, wherein the anisotropic etching comprises reactive ion etching.

20. The method according to claim 12, wherein the step of conformably depositing the charge trapping layer comprises depositing a oxide/nitride/oxide-layer stack as the charge trapping layer.

21. The method according to claim 20, wherein the oxide/nitride/oxide-layer stack has a thickness of less than about 50 nm.

22. The method according to claim 20, wherein the oxide/nitride/oxide-layer stack has a thickness in a range between about 5 nm and 30 nm.

23. The method according to claim 12, wherein the conductive layer is deposited as a poly-silicon layer and arranged such that the regions above the top surface of the protruding elements are filled by the conductive layer.

24. The method according to claim 12, wherein the conductive layer further comprises a layer stack, the layer stack including a metal layer or a metal silicide compound layer.

25. The method according to claim 12, wherein the step of forming a dielectric liner comprises oxidation of the substrate.

26. The method according to claim 12, wherein the step of forming a dielectric liner comprises depositing a silicon dioxide layer.

27. The method according to claim 26, wherein the silicon dioxide layer is deposited as a high temperature oxide.

28. The method according to claim 12, wherein the further conductive layer is deposited as a poly-silicon layer.

29. The method according to claim 28, wherein the further conductive layer is conformably deposited and wherein after the step of depositing the further conductive layer the following steps are performed:
depositing a further resist layer on the surface of the mask layer;
lithographically patterning the further resist layer to form a further patterned resist layer;
removing the further conductive layer outside the further patterned resist layer by etching; and
removing the further patterned resist layer.

30. The method according to claim 12, wherein a lateral dimension of the structural elements of the mask layer is defined by a minimum resolution F of a photolithographic projection apparatus.

31. The method according to claim 30, wherein the step of etching the semiconductor wafer is performed so as to result in a thickness of the protruding elements being less than the minimum resolution F.

32. The method according to claim 31, wherein the thickness is approximately half of the minimum resolution F.

33. The method according to claim 12, wherein the spacer dielectric layer is deposited as a silicon dioxide layer.

34. The method according to claim 12, wherein the spacer dielectric layer is conformably deposited and wherein after the step of depositing the spacer dielectric layer the following steps are performed:
depositing a further resist layer on the surface of the mask layer;
lithographically patterning the further resist layer to form a further patterned resist layer;
removing the spacer dielectric layer outside the further patterned resist layer by etching; and
removing the further patterned resist layer.

35. The method according to claim 12, wherein prior to the step of forming a dielectric liner the charge trapping layer is removed within the regions above the top surface of the protruding elements.

36. The method according to claim 12, wherein prior to the step of partially removing the structural elements of the mask layer the following steps are performed:
forming an implantation mask on the surface of the semiconductor wafer, the implantation mask comprising a plurality of first openings defining a plurality of first implanting region being arranged above the protruding elements; and
implanting ions having a first energy through the plurality of first openings at least partially into the semi-conductive substrate.

37. A method for fabricating a nonvolatile memory, comprising the steps of:
providing a semiconductor wafer, the semiconductor wafer having a semi-conductive substrate;
conformably depositing an charge trapping layer on a surface of the semi-conductive substrate;
depositing a mask layer on the charge trapping layer;
patterning the mask layer to form a plurality of structural elements of the mask layer on the charge trapping layer, the plurality of structural elements structural elements being arranged substantially parallel to each other at a predetermined distance;
etching the charge trapping layer between the plurality of structural elements of the mask layer;
etching the semiconductor wafer to form a plurality of recesses between the structural elements of the mask layer, each of the recesses having substantially vertical sidewalls and a substantially planar bottom surface in order to define plurality of fins having a top surface as protruding elements of the semiconductor wafer;
depositing an dielectric layer on the bottom surface of the plurality of recesses between the fins, the dielectric layer being arranged in a respective region between the bottom surface and a top side of the structural elements;
partially removing the structural elements of the mask layer in regions above the top surface of the protruding elements;
recessing the dielectric layer, the dielectric layer being arranged in a respective region between the bottom surface up to a height below the top surface of the protruding elements;
forming a dielectric liner, the dielectric liner being arranged in each of the regions above the top surface of the protruding elements and forming a gate dielectric on the planar top surface and the sidewalls of the protruding elements;
depositing a conductive layer on each of the dielectric liner in order to define a plurality of gate lines being arranged substantially perpendicular to the protruding elements;
removing the structural elements of the mask layer;
partially removing the dielectric liner above the charge trapping layer for each of the regions;
depositing a further conductive layer on the side walls of each of the gate line above the charge trapping layer;
patterning the charge trapping layer using the further conductive layer and the gate lines as a mask;
depositing a spacer dielectric layer on the side walls of each of the further conductive layer and the patterned charge trapping layer; and
implanting the top surfaces of the protruding elements to define a plurality of source/drain-regions using the spacer dielectric layer as a mask.

38. The method according to claim 37, wherein at least sixteen gate lines are formed.

39. The method according to claim 38, wherein at least thirty-two gate lines are formed.

40. The method according to claim 38, wherein the nonvolatile memory is capable of storing at least 1 Gb of data.

41. A nonvolatile memory cell, comprising:
a semiconductor wafer having a protruding element forming a fin, the fin having a top surface;
a FinFET transistor being arranged on the fin;
a first charge trapping layer being arranged on the top surface of the fin;
a second charge trapping layer being arranged on the planar top surface of the fin, wherein the FinFET transistor further comprises a gate electrode and a gate dielectric layer being arranged at least partially on sidewalls of the fin, the gate electrode being connected to the first charge trapping layer and the second charge trapping layer.

42. A method for fabricating a nonvolatile memory cell, comprising the steps of:
providing a semiconductor wafer, the semiconductor wafer having a semi-conductive substrate;
conformably depositing a charge trapping layer on a surface of the semi-conductive substrate;
conformably depositing a mask layer on the charge trapping layer;
patterning the mask layer to form structural elements of the mask layer on the charge trapping layer, the structural elements being arranged substantially parallel to each other at a predetermined distance;
etching the charge trapping layer between the structural elements of the mask layer;
etching the semiconductor wafer to form recesses between the structural elements of the mask layer, each of the recesses having substantially vertical sidewalls and a substantially planar bottom surface in order to define protruding elements having a top surface;
depositing a dielectric layer on the bottom surface of the recesses between the fins, the dielectric layer being arranged in a region between the bottom surface and a top side of the structural elements;
removing the structural elements of the mask layer;
conformably depositing a further mask layer on the semiconductor wafer;
arranging a patterned resist layer on the further mask layer to form openings above the protruding elements;
etching the charge trapping layer and the further mask layer within the openings;
removing the patterned resist layer;
etching the dielectric layer and the protruding elements, so as to recess the dielectric layer, the dielectric layer being arranged in a region between the bottom surface up to a predetermined height below the top surface of the protruding elements and to form a groove within the protruding elements ranging from the planar top surface to the predetermined height;
forming a dielectric liner, the dielectric liner being arranged on a bottom surface of the groove and on sidewalls of the groove and on sidewalls of the patterned charge trapping layer, the dielectric liner forming a gate dielectric;
depositing a conductive layer on the dielectric liner in order to define a gate line being arranged substantially perpendicular to the protruding elements;
removing the further mask layer;
depositing a further conductive layer on the side walls of the gate lines above the charge trapping layer;
patterning the charge trapping layer using the further conductive layer and the gate lines as a mask;
depositing a further dielectric liner on the semiconductor wafer; and
implanting the top surfaces of the protruding elements to define source/drain-regions outside the gate lines and the further conductive layer.

43. The method according to claim 42, wherein the step of depositing a mask layer on the surface of the charge trapping layer comprises conformably depositing a silicon nitride layer as the mask layer.

44. The method according to claim 43, wherein the step of patterning the mask layer comprises:
depositing a resist layer on the surface of the mask layer;
lithographically patterning the resist layer to form a patterned resist layer;
removing the mask layer outside the patterned resist layer by etching to form the structural elements of the mask layer; and
removing the patterned resist layer.

45. The method according to claim 42, wherein the step of etching the semiconductor wafer selective to the structural elements of the patterned mask layer comprises employing an anisotropic etching.

46. The method according to claim 45, wherein the anisotropic etching comprises reactive ion etching.

47. The method according to claim 42, wherein the step of depositing an dielectric layer on the bottom surface of the recesses comprises:
conformably depositing the dielectric layer as a silicon dioxide layer;
chemical mechanical polishing dielectric layer to remove the dielectric layer from the structural elements of the mask.

48. The method according to claim 42, wherein the step of removing the structural elements comprises a wet etching step.

49. The method according to claim 42, wherein the further mask layer comprises a silicon nitride layer.

50. The method according to claim 42, wherein the step of conformably depositing the charge trapping layer comprises depositing a oxide/nitride/oxide-layer stack as the charge trapping layer.

51. The method according to claim 50, wherein the oxide/nitride/oxide-layer stack has a thickness less than about 50 nm.

52. The method according to claim 50, wherein the oxide/nitride/oxide-layer stack has a thickness between about 5 nm and 30 nm.

53. The method according to claim 42, wherein the conductive layer is deposited as a poly-silicon layer and arranged such that the regions below the top surface of the protruding elements are filled by the conductive layer.

54. The method according to claim 42, wherein the step of forming a dielectric liner comprises oxidation of the substrate.

55. The method according to claim 42, wherein the step of depositing a dielectric liner comprises depositing a silicon dioxide layer.

56. The method according to claim 42, wherein the step of depositing a dielectric liner comprises:
conformably depositing the dielectric liner as a silicon dioxide layer;
chemical mechanical polishing dielectric liner to remove the dielectric liner from the further patterned mask layer; and
filling the groove with the conductive layer;
recessing the conductive layer;
etching the dielectric liner in a region above the recessed conductive layer; and
depositing a metal containing layer on top of the recessed conductive layer.

57. The method according to claim 56, wherein the metal containing layer comprises tungsten or tungsten silicide.

58. The method according to claim 42, wherein the further conductive layer is deposited as a poly-silicon layer.

59. The method according to claim 42, wherein the further conductive layer is conformably deposited and wherein after the step of depositing the further conductive layer the following steps are performed:
depositing a further resist layer on the surface of the mask layer;
lithographically patterning the further resist layer to form a further patterned resist layer;
removing the further conductive layer outside the further patterned resist layer by etching; and
removing the further patterned resist layer.

60. The method according to claim 42, wherein a lateral dimension of the structural elements of the mask layer is defined by a minimum resolution F of a photolithographic projection apparatus.

61. The method according to claim 42, wherein the step of etching the semiconductor wafer forms protruding elements having a height about 200 nm or less.

62. The method according to claim 42, wherein the step of etching the semiconductor wafer forms protruding elements about 200 nm or less apart.

63. The method according to claim 42, wherein the spacer dielectric layer comprises silicon dioxide.

64. The method according to claim 42, wherein the spacer dielectric layer is conformably deposited and wherein after the step of depositing the spacer dielectric layer the following steps are performed:
depositing a further resist layer on the surface of the mask layer;
lithographically patterning the further resist layer to form a further patterned resist layer;
removing the spacer dielectric layer outside the further patterned resist layer by etching; and
removing the further patterned resist layer.

65. The method according to claim 42, wherein the dielectric liner is deposited by a re-oxidizing silicon dioxide layer.

66. The method according to claim 42, wherein prior to the step of partially removing the structural elements of the mask layer the following steps are performed:
forming an implantation mask on the surface of the semiconductor wafer, the implantation mask comprising a plurality of first openings defining a plurality of first implanting region being arranged above the protruding elements; and
implanting ions having a first energy through the plurality of first openings at least partially into the semi-conductive substrate.

67. A method for fabricating a nonvolatile memory, comprising the steps of:
providing a semiconductor wafer, the semiconductor wafer having a semi-conductive substrate;
conformably depositing an charge trapping layer on a surface of the semi-conductive substrate;
conformably depositing a mask layer on the charge trapping layer;
patterning the mask layer to form a plurality of structural elements of the mask layer on the charge trapping layer, the plurality of structural elements being arranged substantially parallel to each other at a predetermined distance;
etching the charge trapping layer between the plurality of structural elements of the mask layer;
etching the semiconductor wafer to form a plurality of recesses between the structural elements of the mask layer, each of the recesses having substantially vertical sidewalls and bottom surfaces in order to define a plurality of protruding elements having a top surface;
depositing an dielectric layer on each of the bottom surface of the recesses between the fins, the dielectric layer being arranged in a respective region between the bottom surface and a top side of the structural elements;
removing the structural elements of the mask layer;
conformably depositing a further mask layer on the semiconductor wafer;
arranging a patterned resist layer on the further mask layer to form a plurality of openings above the protruding elements;
etching the charge trapping layer and the further mask layer within the plurality of openings;
removing the patterned resist layer;
etching the dielectric layer and the protruding elements, so as to recess the dielectric layer, the dielectric layer being arranged in a respective region between the bottom surface up to a predetermined height below the top surface of the protruding elements and to form a plurality of grooves within the protruding elements ranging from the planar top surface to the predetermined height;
forming a dielectric liner, the dielectric liner being arranged on a bottom surface of the plurality of grooves and on sidewalls of the plurality of grooves and on sidewalls of the patterned charge trapping layer, the dielectric liner forming a gate dielectric;
depositing a conductive layer on the dielectric liner in order to define a plurality of gate lines being arranged substantially perpendicular to the protruding elements;
removing the further mask layer;
depositing a further conductive layer on the side walls of the gate lines above the charge trapping layer;
patterning the charge trapping layer using the further conductive layer and the plurality of gate lines as a mask;
depositing a further dielectric liner on the semiconductor wafer; and
implanting the top surfaces of the protruding elements to define a plurality of source/drain-regions outside the gate lines and the further conductive layer.

68. The method according to claim 67, wherein at least sixteen gate lines are formed.

69. The method according to claim 68, wherein at least thirty-two gate lines are formed.

70. The method according to claim 68, wherein the nonvolatile memory may store at least 1 Gb of data.

71. A nonvolatile memory cell, comprising:
a semiconductor wafer having a protruding element, the protruding element having a top surface;
a u-shaped transistor being arranged within the protruding element;
a first charge trapping layer being arranged on the top surface of the protruding element; and
a second charge trapping layer being arranged on the planar top surface of the protruding element, wherein the u-shaped transistor comprises a gate electrode and a gate dielectric layer being arranged on sidewalls of a groove within the protruding element, the gate electrode being connected to the first charge trapping layer and the second charge trapping layer.
